(19) United States
(12) Patent Application Publication
(10) Pub. No.: US 2024/0172392 A1
(43) Pub. Date: May 23, 2024

(54) SYSTEM FOR HARNESSING HEAT GENERATED BY INTENSIVE PROCESSES

(71) Applicant: Shelby Korpi, Oro Valley, AZ (US)

(72) Inventors: Shelby Korpi, Oro Valley, AZ (US); Mark F Miller, III, Britt, IA (US); Ondrej Dvorak, San Diego, CA (US)

(21) Appl. No.: 18/514,988

(22) Filed: Nov. 20, 2023

Related U.S. Application Data
(60) Provisional application No. 63/384,561, filed on Nov. 21, 2022.

(51) Int. Cl. H05K 7/20

(52) U.S. Cl. CPC H05K 7/20263; H05K 7/20236; H05K 7/20272

(57) ABSTRACT

A heat harnessing apparatus, comprising: one or more waste heat sources; one or more immersion tanks; one or more pumps; and one or more heat exchangers. The immersion tanks, the pumps, and the heat exchangers are filled with fluid, and are in fluidic communication with each other through a series of pipes. The immersion tanks are configured to support one or more waste heat sources and allow the fluid to be in fluidic communication with the waste heat sources. The waste heat sources are configured to transfer a waste heat to the fluid; wherein the pumps pump the fluid and the heat waste into the heat exchangers. The heat exchangers are configured to remove the generated heat from the fluid. The pumps, pump the fluid with the generated heat removed into the immersion tanks.

### CROSS-REFERENCE TO RELATED APPLICATIONS

This Non-Provisional application claims the benefit of and priority to U.S. Provisional Patent Application No. 63/384,561, filed on Nov. 21, 2022, titled System for Harnessing Heat Generated By Intensive Processes, the contents of which are expressly incorporated herein by this reference as though set forth in their entirety and to which priority is claimed.

### FIELD OF USE

The present disclosure relates, in general, to a system and method of harnessing otherwise wasted heat energy produced from intensive computer processing. More specifically, the present disclosure relates to a system for harnessing the wasted heat generated by computers for the benefit of livestock.

### BACKGROUND

Generally, computers generate heat, and that heat is produced by the electricity working inside the computer. As electricity flows through the various circuits and resistors inside the machine, some of that energy is “lost” and becomes heat. It's similar to a light bulb, where current runs through a wire and gets hot, glowing from the heat.

Computer processes requiring rigorous calculations generate heat as a waste byproduct. Typically, liquid or air-cooling apparatus are used to specifically siphon heat away from those particular components that tend to generate or experience the greatest amount of heat.

In air cooling systems, fans push air through radiators, wherein the radiators are in contact with heat generating components through a heat sink.

In liquid cooled systems, liquid is contained in a closed system having a reservoir, tubing, radiator, and heat sinks, wherein the heat sinks are in contact with heat generating components and liquid is pumped through the tubing to capture heat from the heat sinks and then pushed to radiators to cool off. The reservoir may act as a secondary cooling system in scenarios where the radiator is unable to effectively cool the liquid.

Importantly, these systems target specific heat generating components rather than entire computer systems. One reason for this sort of targeted approach is that while computers generate heat, the vast majority of heat is generated by a limited number of components, such as the central processing unit or graphical processing unit.

Crypto mining systems and operations tend to be highly focused on maximizing processing power at the expense of substantially any other normal computer process. Because of the high amount of heat generated by these systems, and because these systems tend to be relatively compact in nature, keeping these systems cool can be difficult. Moreover, keeping these systems cool increases their efficiency and potential profitability of running such a system.

In May 2023, Bitcoin mining was estimated to consume around 95.58 terawatt-hours of electricity. Of which is nearly all converted to heat energy. One watt is equivalent to 3.421 British Thermal Units (“BTU”) which is also equivalent to 1 Joule (“J”). This equates to approximately 95.58 joules-hour of energy or 326.97 tera-BTU of heat energy.

When many crypto mining systems or server farms are in an enclosed space, they require external air conditioning and ventilation systems to remove the heat and vent it away from the systems or servers. This additional air conditioning and ventilation adds to the inefficiencies in wasting the produced heat.

Utilizing this wasted heat is desirable but transferring thermal energy to a usable area typically leads to substantial losses reducing the efficiency of the harnessed heat.

Thus, what is needed is a system for utilizing the heat produced from crypto mining systems and utilizing the heat without transportation losses instead of wastefully venting it away, or even introducing additional power usage such as by air conditioning.

### SUMMARY

To minimize the limitations in the prior art, and to minimize other limitations that will become apparent upon reading and understanding the present specification, the present disclosure discloses a new and useful system for harnessing the wasted heat generated by computers.

The following presents a simplified overview of the example embodiments in order to provide a basic understanding of some embodiments of the example embodiments. This overview is not an extensive overview of the example embodiments. It is intended to neither identify key or critical elements of the example embodiments nor delineate the scope of the appended claims. Its sole purpose is to present some concepts of the example embodiments in a simplified form as a prelude to the more detailed description that is presented herein below. It is to be understood that both the following general description and the following detailed description are exemplary and explanatory only and are not restrictive.

Mobile heat harnessing heat is a mobile heating unit that utilizes the wasted heat generated by intensive computing devices.

One embodiment of the present disclosure may comprise a heat source, a fluid, a heat exchanger, and a fan, which are operatively, thermally, and electrically connected to each other and a ventilation system. A heat source may be immersed in a fluid that transfers generated heat to a fluid. The fluid transports the absorbed generated heat to a heat exchanger, where a fan removes it. The removed heat may then be used to heat a space or area.

The heat generated by a computer, computer server, or cryptominers may lead to electronic failures if not removed. It is preferable that the heat removed be utilized in order to reduce waste and losses in efficiency.

One embodiment of a heat harnessing apparatus of the present disclosure may comprise: waste heat sources; immersion tanks; pumps; and heat exchangers; wherein the immersion tanks, the pumps, and the heat exchangers may contain an immersion fluid; wherein the pumps may be configured to pump the immersion fluid from the immersion tanks to and from the heat exchangers through an immersion-exchanger pipe system; wherein the immersion tanks may contain a waste heat sources in fluidic communication with the immersion fluid; wherein the waste heat sources may be configured to transfer a generated heat to the immersion fluid. The immersion fluid may be a dielectric fluid. The immersion fluid may be a Bitcool dielectric fluid. The waste heat sources may be cryptominers. The pumps may be configured to be submersed in the immersion fluid; wherein the pumps, pump the immersion fluid and the generated heat into the heat exchangers; whereby the heat exchangers may remove the generated heat from the immersion fluid; wherein the pumps, pump the immersion fluid with the generated heat removed into the immersion tanks. The heat exchangers may be configured to transfer heat to one or more radiators. The radiators may further include fans; wherein the fans may be configured to circulate a flow of air; whereby the flow of air may flow through the radiators; whereby the flow of air may remove the generated heat from the radiators; and the flow of air may heat a space with the generated heat. The system may be a mobile heating apparatus; wherein the mobile heating apparatus may transfer the generated heat to one or a combination of rooms, spaces, or buildings. The system may further comprise; a thermal sensor; and displays; wherein the thermal sensors may be configured to measure the temperature of the waste heat sources; and wherein the displays may be configured to display one or more system parameters and status.

Another embodiment of a heat harnessing apparatus may comprise: one or more cryptominers; an immersion tank; pumps; and heat exchangers; wherein the immersion tanks, the pumps, and the heat exchangers may contain an immersion fluid; wherein the pumps may be configured to pump the immersion fluid from the immersion tank to and from the heat exchangers through an immersion-exchanger pipe system; wherein the immersion tank may contain cryptominers in fluidic communication with the immersion fluid; wherein the cryptominers may be configured to transfer a generated heat to the immersion fluid. The cryptominers may be stacked into an array. The heat harnessing apparatus may further comprise a fan; wherein the fan may be configured to circulate surrounding air through the radiator. The circulated air may heat one or more of a combination of spaces, rooms, or a building. The heat harnessing apparatus may further comprise ventilation ducts; wherein the ventilation ducts may be configured to allow a circulated air flow through the ventilation ducts. The circulated air flow may transfer the harnessed heat throughout one or a combination of rooms, spaces, or building. The pumps may be submersed in the immersion fluid in the immersion tanks; wherein the pumps, pump the fluid and the generated heat into the heat exchangers; wherein the heat exchangers may be configured to remove the generated heat from the fluid; wherein the pumps, pump the fluid with the generated heat removed into the immersion tanks.

Another embodiment of a heat harnessing apparatus may comprise: one or more computing devices; immersion tanks; pumps; and heat exchangers; wherein the immersion tanks may be configured to contain an immersion fluid; wherein the pumps may be configured to pump the immersion fluid from the immersion tanks to and from the heat exchangers though an immersion-exchanger pipe system; wherein the immersion tanks may comprise a cooled fluid inlet and a heated fluid outlet, wherein the fluid may be configured to enter the immersion tank through the cooled fluid inlet and the immersion fluid may be configured to exit the immersion tanks through the heated outlet; wherein the immersion tanks may be configured to support the computing devices; wherein the immersion fluid may be configured to be in fluidic communication with the computing devices; and wherein the computing devices may be configured to generate heat, and when in contact with the immersion fluid, may be configured to transfer the generated heat to the immersion fluid. The heat harnessing apparatus may further comprise fans and dissipation systems; wherein the dissipation systems comprise dissipator pumps, radiators and exchanger-dissipation pipe systems; wherein the exchanger-dissipation pipe systems contain a dissipation fluid; wherein the exchanger-dissipation pipe systems may be configured to transfer heat from the heat exchangers to the radiators; wherein the fans may be configured to blow an ambient air to transfer heat from the radiators to an outside environment. The outside environment may be an agricultural setting. The heat harnessing apparatus may further comprise air filters configured to prevent contaminants in the outside environment from interacting with the dissipation systems.

It is an object to overcome the limitations of the prior art.

These, as well as other components, steps, features, objects, benefits, and advantages, will now become clear from a review of the following detailed description of illustrative embodiments, the accompanying drawings, and the claims.

### BRIEF DESCRIPTION OF THE DRAWINGS

The drawings are of illustrative embodiments. They do not illustrate all embodiments. Other embodiments may be used in addition or instead. Details which may be apparent or unnecessary may be omitted to save space or for more effective illustration. Some embodiments may be practiced with additional components or steps and/or without all of the components or steps which are illustrated. When the same numeral appears in different drawings, it refers to the same or like components or steps.

FIG. 1 is a block diagram of a heat harnessing heater.

FIG. 2 is an embodiment of a fluid flow through a heat harnessing heater using multiple radiators.

FIG. 3 is an illustration of a mobile heat harnessing heater.

FIG. 4 is a front cross-sectional view of a mobile heat harnessing heater.

FIG. 5 is a block diagram of a heat harnessing heater lid architecture.

FIG. 6 is a block diagram of a heat harnessing heater heat generating side fluid flow.

FIG. 7 is a block diagram of a heat harnessing heater electrical architecture.

FIG. 8 is an alternate embodiment of a heat harnessing heater for a large space.

### DETAILED DESCRIPTION OF THE ILLUSTRATIVE EMBODIMENTS

In the following detailed description of various embodiments of the present disclosure, numerous specific details are set forth in order to provide a thorough understanding of various aspects of one or more embodiments of the present disclosure. However, one or more embodiments of the present disclosure may be practiced without some or all of these specific details. In other instances, well-known methods, procedures, and/or components have not been described in detail so as not to unnecessarily obscure aspects of embodiments of the present disclosure.

While multiple embodiments are disclosed, still other embodiments of the devices, systems, and methods of the present disclosure will become apparent to those skilled in the art from the following detailed description, which shows and describes illustrative embodiments of the devices, systems, and methods of the present disclosure. As will be realized, the devices, systems, and methods of the present disclosure are capable of modifications in various obvious aspects, all without departing from the spirit and scope of the present disclosure. Accordingly, the screenshot figures, and the detailed descriptions thereof, are to be regarded as illustrative in nature and not restrictive. Also, the reference or non-reference to a particular embodiment of the devices, systems, and methods of the present disclosure shall not be interpreted to limit the scope of the present disclosure.

Before the present methods and systems are disclosed and described, it is to be understood that the methods and systems are not limited to specific methods, specific components, or to particular implementations. It is also to be understood that the terminology used herein is for the purpose of describing particular embodiments only and is not intended to be limiting.

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint.

“Optional” or “optionally” means that the subsequently described event or circumstance may or may not occur, and that the description includes instances where said event or circumstance occurs and instances where it does not.

Throughout the description and claims of this specification, the word “comprise” and variations of the word, such as “comprising” and “comprises,” means “including but not limited to,” and is not intended to exclude, for example, other components, integers or steps. “Exemplary” means “an example of” and is not intended to convey an indication of a preferred or ideal embodiment. “Such as” is not used in a restrictive sense, but for explanatory purposes.

Disclosed are components that may be used to perform the disclosed methods and systems. These and other components are disclosed herein, and it is understood that when combinations, subsets, interactions, groups, etc. of these components are disclosed that while specific reference of each various individual and collective combinations and permutation of these may not be explicitly disclosed, each is specifically contemplated and described herein, for all methods and systems. This applies to all embodiments of this application including, but not limited to, steps in disclosed methods. Thus, if there are a variety of additional steps that may be performed it is understood that each of these additional steps may be performed with any specific embodiment or combination of embodiments of the disclosed methods.

The present methods and systems may be understood more readily by reference to the following detailed description of preferred embodiments and the examples included therein and to the Figures and their previous and following description.

In the following description, certain terminology is used to describe certain features of one or more embodiments. For purposes of the specification, unless otherwise specified, the term “substantially” refers to the complete or nearly complete extent or degree of an action, characteristic, property, state, structure, item, or result. For example, in one embodiment, an object that is “substantially” located within a housing would mean that the object is either completely within a housing or nearly completely within a housing. The exact allowable degree of deviation from absolute completeness may in some cases depend on the specific context. However, generally speaking, the nearness of completion will be so as to have the same overall result as if absolute and total completion were obtained. The use of “substantially” is also equally applicable when used in a negative connotation to refer to the complete or near complete lack of an action, characteristic, property, state, structure, item, or result.

As used herein, the terms “approximately” and “about” generally refer to a deviance of within 5% of the indicated number or range of numbers. In one embodiment, the term “approximately” and “about”, may refer to a deviance of between 0.001-40% from the indicated number or range of numbers.

Various embodiments are now described with reference to the drawings. In the following description, for purposes of explanation, numerous specific details are set forth in order to provide a thorough understanding of one or more embodiments. It may be evident, however, that the various embodiments may be practiced without these specific details. In other instances, well-known structures and devices are shown in block diagram form to facilitate describing these embodiments.

As used herein, the term “British thermal unit” or “BTU” refers to a measure of the heat content of fuels or energy sources.

As used herein, the term “computer” refers to a machine that can be programmed to automatically carry out sequences of arithmetic or logical operations (computation).

As used herein, the term “array of computers” or “array” refers to a group of computers that may be connected and arranged in a structure to form a single grouping of computers.

As used herein, the term “computing device” refers to a general-purpose machine that executes instructions for any data processing purpose.

As used herein, the term “computer server” refers to a computer program or device that provides services to other computers.

As used herein, the term “Crypto” or “cryptocurrency” refers to a digital currency designed to work as a medium of exchange through a computer network that is not reliant on any central authority, such as a government or bank, to uphold or maintain it. It is a decentralized system for verifying that the parties to a transaction have the money they claim to have, eliminating the need for traditional intermediaries, such as banks, when funds are being transferred between two entities.

As used herein, the term “crypto mining” or “mining” refers to verifying and adding new cryptocurrency to a blockchain.

As used herein, the term “cryptominers” refers to computation devices that solve complex mathematical equations to verify cryptocurrency transactions. Typically, application-specific integrated circuit (“ASIC”) computers which are powerful, tailor-made machines for mining.

As used herein, the term “decentralized system” refers to new paradigms that leverage distributed ledger technologies to offer services such as lending, investing, or exchanging crypto assets without relying on a traditional centralized intermediary.

As used herein, the term “dielectric” refers to a material that doesn't allow current to flow.

As used herein, the term “dielectric fluid” refers to an electrically non-conductive liquid that can transfer heat.

As used herein, the term “distribution ledger” refers to a database held and updated independently by each participant (or node) in a large network.

As used herein, the term “thermal energy,” “heat energy,” or “heat” refers to the energy that an object has due to the movement of its molecules.

As used herein, the term “HVAC duct” or “duct” refers to conduits or passages used in heating, ventilation, and air conditioning (HVAC) to deliver and remove air.

As used herein, the term “joule” refers to the SI unit of work or energy, equivalent to one 1 watt per second.

As used herein, the term “poultry coop” or “chicken coup” refers to a structure where fowls such as chickens, turkeys, ducks, and geese live and get shelter from weather and predators.

As used herein, the term “watt” refers to the SI unit of power, equivalent to one joule per second, corresponding to the power in an electric circuit in which the potential difference is one volt and the current one ampere.

A typical computer server consumes 500-1200 watts, and a cryptominer may consume 500-3050 watts of electrical energy. Almost 100% of the electrical energy consumed by a computer, computer server, or cryptominers is converted to thermal heat. One (1) watt of electrical energy converts to 3.41 British Thermal Units (“BTU”) per hour. The typical computer may generate 1705-4092 BTU per hour, and a cryptominer may generate 1705-10,370 BTU per hour of wasted thermal energy or heat.

The typical heating requirements of a space may be determined by the following formula: (desired temperature change)×(cubic feet of space)×0.133=BTUs needed per hour to heat.

It is preferable to remove all the heat generated from a computer, computer server, or cryptominers to prevent electronic failures.

In order to maximize efficiency and reduce thermal losses in transporting the harnessed heat, it is preferable that the source of the generated heat is near the intended use of the harnessed heat.

Heating needs fluctuate, and it is often preferable to configure a heat harnessing system as a mobile heat harnessing apparatus and heater in order to harness and utilize the generated heat more efficiently.

A mobile heat harnessing apparatus may comprise a source that generates heat or wasted heat, a medium for removing the generated heat or waste heat from the heat source, and a ventilation system where the harnessed heat may be transferred to heat a space.

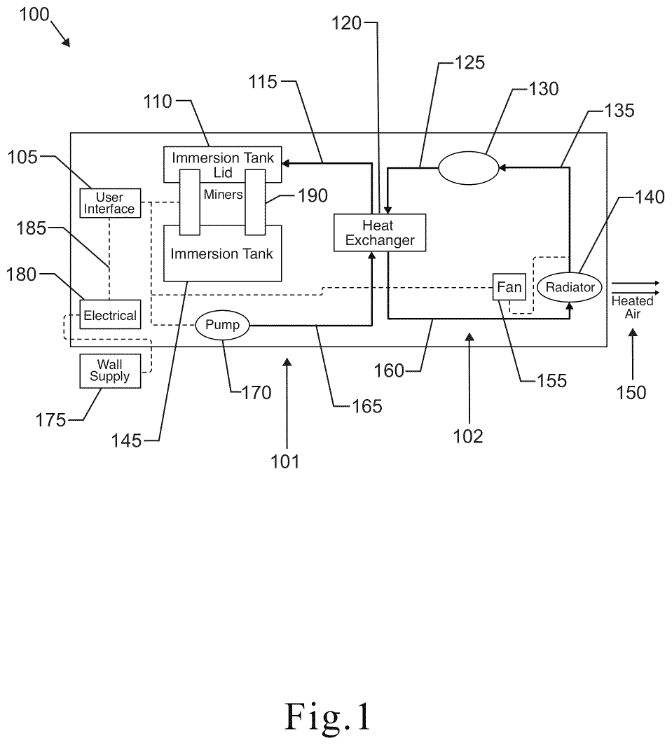

FIG. 1 is a block diagram of a heat harnessing system. The heat harnessing system 100 may comprise a heat generating side 101, a space heating side 102, a user interface 105, an immersion tank lid 110, an heat exchanger removed heat return pipe 115, a heat exchanger 120, a heat exchanger cool return pipe 125, a ventilation fluid pump 130, a radiator cooled return pipe 135, a radiator 140, an immersion tank 145, an ventilated air 150, a fan 155, a heat exchanger radiator supply pipe 160, a heat exchanger removed heat inlet pipe 165, a heat harnessing fluid pump 170, a commercial AC power outlet 175, a heat harnessing power distributor 180, heat harnessing apparatus data bus lines 185, and a heat source 190.

The heat generating side 101 may refer to portion of the heat exchanger 120 that is configured to transfer heat to the space heating side 102. The space heating side 102 may be the side of heat exchanger 120 that is configured to provide heat to a space. Preferably, the space may be adjacent to the heat harnessing system 100, or may be in temperature-based communication thereof. In some embodiments, the space may be a location configured to house livestock or animals.

The user interface 105 may be a point of interaction or communication terminal between different components, subsystems, or systems within the heat harnessing system 100. The user interface 105 may provide users with notifications regarding warnings, temperature, electrical usage, efficiency, system status, and miscellaneous other parameters that the user interface 105 may be configured to monitor.

The immersion tank lid 110 may provide inlets and outlet fittings for pipes, electrical cables, communication cables, and sensors. The heat exchanger removed heat return pipe 115, and heat exchanger removed heat inlet pipe 165 may allow fluid to pass in and out of the immersion tank 145 and heat exchanger 120. The heat exchanger 120 may be a device, structure, apparatus, or material configured to transfer heat from one medium to another medium. The ventilation fluid pump 130 may pump fluid in and out of the heat exchanger 120 and radiator 140. The radiator cooled return pipe 135, and heat exchanger radiator supply pipe 160 may allow fluid to pass in and out of the heat exchanger 120 and radiator 140. The radiator 140 may allow a fluid to pass from a hot side to a cool side and transfer heat to the ventilated air 150. The ventilated air 150 may be moved from one side of the radiator 140 by the fan 155. The heat harnessing fluid pump 170 may pump fluid in and out of the heat exchanger 120 and immersion tank 145. The commercial AC power outlet 175 may be a source of readily available residential or commercial wall power outlet, which may typically operate on 120-volt AC. The heat harnessing power distributor 180 may regulate input electrical power and may distribute electrical power to components, subsystems, or systems. The heat harnessing apparatus data bus lines 185 may allow the heat harnessing system 100 to be controlled by a separate microcontroller or computer that may also control the user interface 105. The heat source 190 may be one or more computers, computer servers, or cryptominers that generate thermal heat from the electricity consumed thereby.

The heat source 190 may be a combination of computers, computer servers, or cryptominers, and the heat harnessing system 100 may be configured to utilize a plurality of computers, computer servers, or cryptominers.

The immersion tank 145 preferably contains the heat source 190 and a fluid. The fluid is preferably a dielectric fluid such as those offered under the names Bitcool™ Dielectric fluid, ChemWold Chiller Coolant™, or Galden® PFPE. Dielectric fluids may be used as electrical insulators in electrical applications. Dielectric fluids may provide electrical insulation, suppress arcing, and serve as a heat transfer fluid. The heat source 190 may generate 1705-10,370 British Thermal Units (“BTU”) per hour. The immersion tank 145 may preferably be configured to contain or house the one or more heat sources 190. The number of heat sources 190 that the immersion tank 145 is configured to contain or house may be determined by the maximum BTU the heat harnessing system 100 is configured to provide. The Environmental Protection Agency (“EPA”) recommends an output of approximately 20 BTUs per 1 square foot (“sqft”) of space for heating. The following formula may be used to determine the amount of BTU recommended to heat a volume: (desired temperature change)×(cubic feet of space)×0.133=BTUs. For example, as shown in FIG. 1, the immersion tank 145 is configured to house two heat sources 190; in this configuration, the heat harnessing system 100 may generate 3,410-20,740 BTU and may be capable of providing heat to a 170-1037 square foot space.

In one embodiment, the heat harnessing system 100 may be designed to generate 20,740 BTU. As the heat source 190 processes information, performs computing tasks, or uses electricity, the heat source 190 generates heat. Fluid may be held within the immersion tank 145 and may conduct or transfer heat from the heat source 190 to the fluid. The heat harnessing fluid pump 170 may pump and circulate fluid through the heat exchanger removed heat inlet pipe 165 into the heat exchanger 120. The heat exchanger 120 may transfer heat between two or more fluids, such as liquids, gases, or a combination of both. The heat exchanger 120 may separate two fluids by a permeable or impermeable barrier to prevent them from mixing. The heat exchanger 120 may allow hot fluid from the immersion tank 145 to cool down, and cool fluid from the radiator 140 to warm up without them actually coming into contact and mixing. The heat harnessing fluid pump 170 may pump fluid that has transferred heat out of the heat exchanger 120 through the heat exchanger removed heat return pipe 115 and may return it to the immersion tank 145 through a fitting in the immersion tank lid 110.

The returned fluid may then again transfer heat from the heat source 190. The ventilation fluid pump 130 may pump a fluid through the heat exchanger cool return pipe 125 into the heat exchanger 120 and absorb heat as it passes through to the heat exchanger radiator supply pipe 160 and may supply a heated fluid to the radiator 140. The fan 155 may ventilate air through the radiator 140, and the ventilated air 150 may increase in temperature as it removes heat from the radiator 140. The ventilated air 150 may circulate heated air through a volume or space to provide heat.

The heat harnessing system 100 may provide generated heat to poultry coops or terrariums where animals, such as domestic fowls and reptiles, would benefit from warmer temperatures.

The heat harnessing system 100 may be used in a small residential space or may be used to provide heat to a large open space.

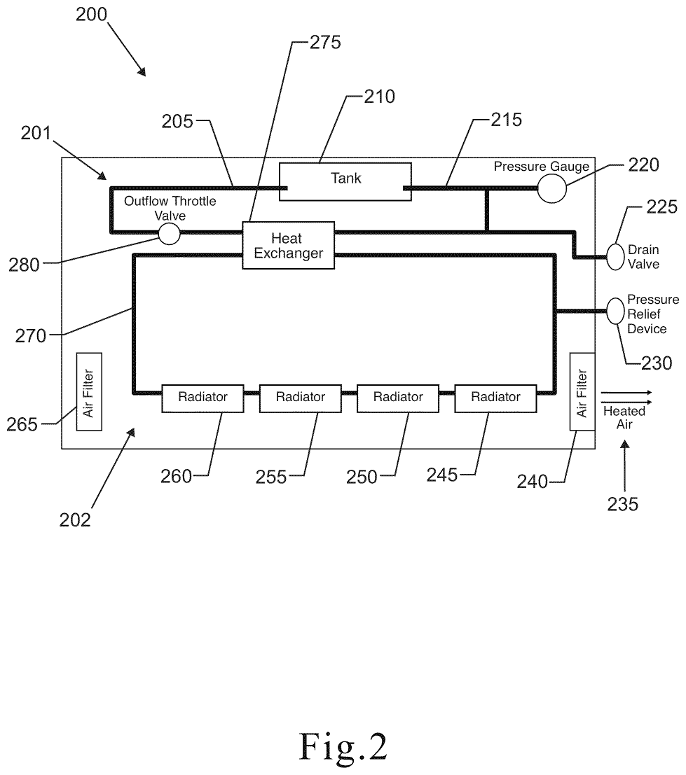

FIG. 2 is an embodiment of a fluid flow through a heat harnessing heater using multiple radiators. The heat harnessing system 200 may comprise a heat generating side 201, a space heating side 202, a heat exchanger radiator supply pipe 205, an immersion tank 210, a heat exchanger removed heat return pipe 215, a pressure gauge 220, a drain valve 225, a pressure relief device 230, a ventilated air 235, an output air filter 240, a first radiator 245, a second radiator 250, a third radiator 255, a fourth radiator 260, an input air filter 265, a heat exchanger radiator supply pipe 270, a heat exchanger 275, and an outflow throttle valve 280.

The heat generating side 201 may be the side of heat exchanger 275 that is configured to transfer heat to the space heating side 202. The space heating side 202 may be the side of the heat exchanger 275 configured to provide heat to a space.

In one embodiment, the space to which heat is being provided may be an agricultural facility, such that this generated heat may be used to keep livestock and animals warmer than regular ambient temperatures. In some embodiments, a duct and fan system may be affixed to the space heating side 202, or in place thereof, in order to allow heat to be transferred to specific locations for specific benefits. Agricultural facilities may also be substantially any location that may benefit from additional heat for the purposes of welfare of animals.

The immersion tank 210 may heat a fluid on the heat generating side 201, and as that fluid is heated, it may flow through the heat exchanger radiator supply pipe 205 through the outflow throttle valve 280. The outflow throttle valve 280 may control the flow of a fluid in order to maximize the heat absorbed by a fluid. The fluid may then flow into the heat generating side 201 of the heat exchanger 275, where it may transfer heat to separate fluid flow on the space heating side 202. Fluid may then exit the heat exchanger 275 through the heat exchanger removed heat return pipe 215. The pressure gauge 220 may indicate the pressure in the heat generating side 201 of the heat generating side 201. If pressure is too great or there is a need to drain the fluid from the heat generating side 201, the drain valve 225 may be used to relieve pressure and drain fluid from heat the generating side 201.

A separate fluid may flow in the space heating side 202 of the heat exchanger 275 from the heat exchanger cool return pipe 271 into the heat exchanger 275. The fluid on the space heating side 202 of the heat exchanger 275 absorbs heat from the heat generating side 201 of the heat exchanger 275. The fluid flows out of the heat exchanger 275 through the heat exchanger radiator supply pipe 270 and may flow through the first radiator 245, the second radiator 250, the third radiator 255, and the fourth radiator 260. The first radiator 245, the second radiator 250, the third radiator 255, and the fourth radiator 260 may have ventilated air pass through them, removing heat from the first radiator 245, the second radiator 250, the third radiator 255, and the fourth radiator 260. The fluid may then flow out of the fourth radiator 260 through the heat exchanger cool return pipe 271 and back to the heat exchanger 120. The heat exchanger cool return pipe 271 may include the pressure relief device 230. If the space heating side 202 experiences excessive pressure within the fluid flow, it may release the excess pressure.

The heat harnessing system 200 may comprise the input air filter 265 and output air filter 240. The input air filter 265 and output air filter 240 may filter out unwanted particles in ventilated air 235 as it passes through the first radiator 245, the second radiator 250, the third radiator 255, and the fourth radiator 260.

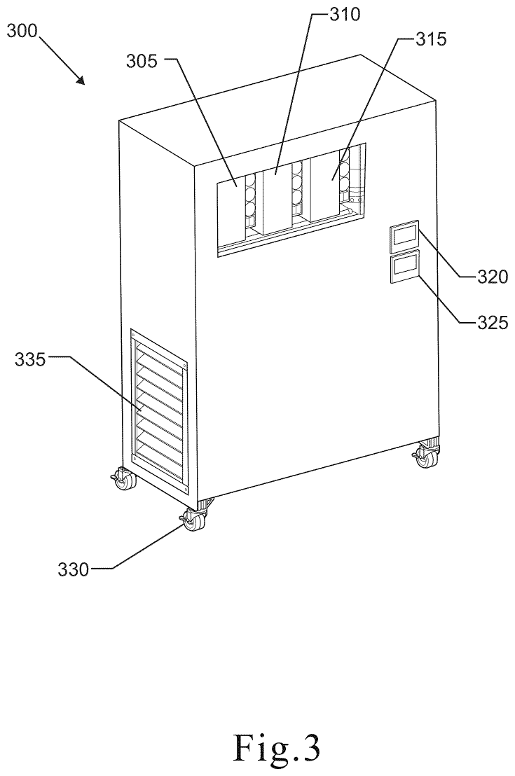

FIG. 3 is an illustration of a mobile heat harnessing system. The mobile heat harnessing system 300 may comprise a first heat source 305, a second heat source 310, a third heat source 315, a first display 320, a second display 325, one or more wheels 330, and one or more vents 335.

The first heat source 305, second heat source 310, and third heat source 315 may be one or more computers, computer servers, or cryptominers and may produce 5,115-31,110 BTU per hour of wasted thermal energy or heat. The mobile heat harnessing system 300 may transfer the wasted thermal heat from the first heat source 305, second heat source 310, and third heat source 315 and use it to heat a space or room out of the vent 335.

The mobile heat harnessing system 300 may be configured to be mobile, as shown in FIG. 3, by configuring the mobile heat harnessing system 300 with the wheels 330.

The first display 320 and the second display 325 may provide an operator status of miscellaneous parameters within the mobile heat harnessing system 300. The first display 320 and second display 325 may also provide an ambient air temperature reading and an output ventilated air temperature readings.

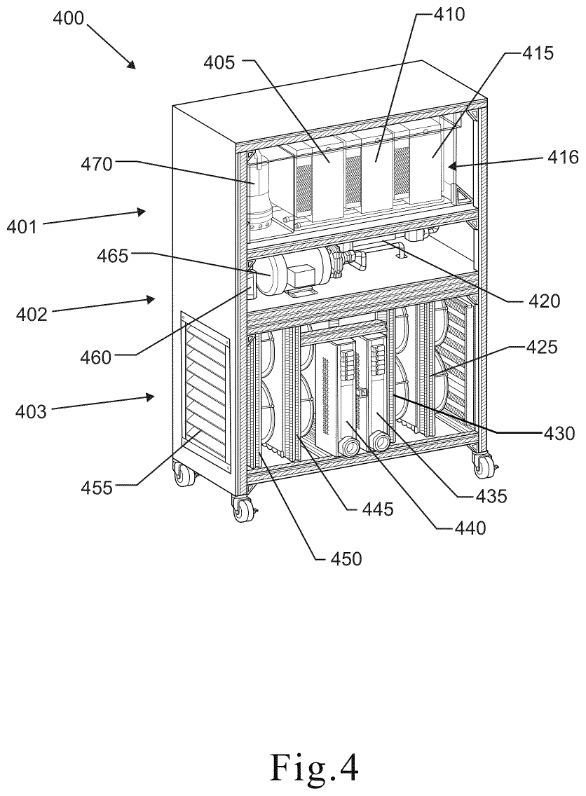

FIG. 4 is a front cross-sectional view of a mobile heat harnessing heater. The mobile heat harnessing system 400 may comprise a first shelf 401, second shelf 402, third shelf 403, first heat source 405, second heat source 410, third heat source 415, immersion tank 416, heat exchanger 420, fourth radiator and fan 425, third radiator and fan 430, second power supply 435, first power supply 440, second radiator and fan 445, first radiator and fan 450, ventilation 455, ethernet switch 460, ventilation fluid pump 465, and heat harnessing fluid pump 470.

The first shelf 401 may support and hold the immersion tank 416. The first heat source 405, second heat source 410, third heat source 415 may be housed or contained in the immersion tank 416. The immersion tank 416 may be constructed from a transparent material such as glass, acrylic, or any other material capable of housing the first heat source 405, second heat source 410, third heat source 415, and a fluid. Using a transparent material for the immersion tank 416 may allow an operator of the mobile heat harnessing system 400 verify the status of the first heat source 405, second heat source 410, and third heat source 415. The heat harnessing fluid pump 470 may be but should not be limited to a submersible pump for fluid. The immersion tank 416 may be transparent.

The second shelf 402 may contain or house the heat exchanger 420, ethernet switch 460, and ventilation fluid pump 465. The ethernet switch 460 may connect the first heat source 405, second heat source 410, and third heat source 415 to a network.

The third shelf 403 may contain or house the fourth radiator and fan 425, third radiator and fan 430, second power supply 435, first power supply 440, second radiator and fan 445, first radiator and fan 450, and ventilation 455.

The immersion tank 416 may contain a fluid that is configured to absorb generated heat from the first heat source 405, second heat source 410, and third heat source 415. The fluid may be pumped by the heat harnessing fluid pump 470 to the heat exchanger 420 which may transfer the heat to a second fluid pumped to the first radiator and fan 450, second radiator and fan 445, third radiator and fan 430, and fourth radiator and fan 425. The first radiator and fan 450, second radiator and fan 445, third radiator and fan 430, and fourth radiator and fan 425 create a ventilated airflow that removes heat from the first radiator and fan 450, second radiator and fan 445, third radiator and fan 430, and fourth radiator and fan 425. The removed heat may then be circulated to heat a room, space, or building.

One or more mobile heat harnessing systems 400 may be used to heat a room, space, or building.

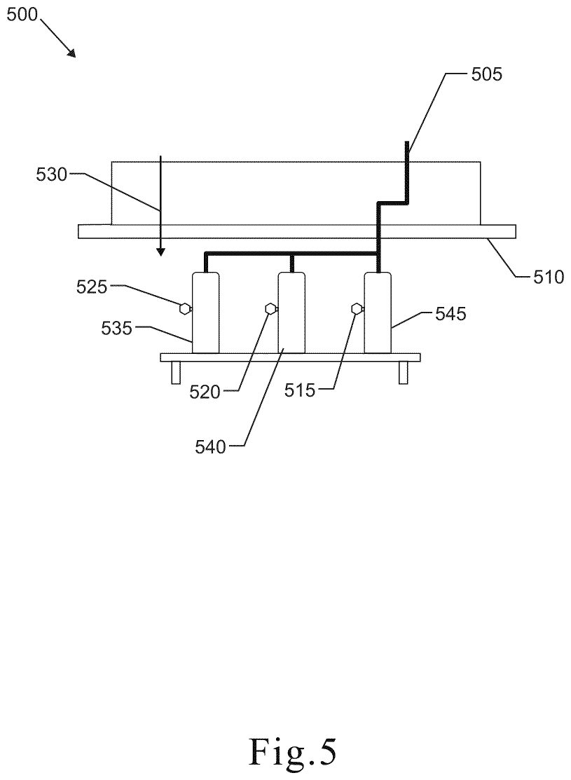

FIG. 5 is a block diagram of a heat harnessing heater lid. The immersion tank lid 500 may comprise an electrical and data inlet and outlet 505, seal 510, third thermal sensor 515, second thermal sensor 520, first thermal sensor 525, and cooled fluid from heat exchanger 530. The immersion tank lid 500 may be constructed of the same material as the immersion tank 416 of FIG. 4 and may provide inlets and outlet fittings for pipes, electrical cables, communication cables, and sensors, and seal the immersion tank 416, as shown in FIG. 4.

The electrical and data inlet and outlet 505 may provide electrical power and network communication connections to the first heat source 535, second heat source 540, and third heat source 545. It is preferable that the electrical and data inlet and outlet 505 enter and exit the immersion tank lid 500 through a sealed bulkhead type connector (not shown). A sealed bulkhead connector may prevent fluid from penetrating electrical connections and retain generated heat within the immersion tank lid 500.

The seal 510 may provide a fluid, thermal, and pressure seal between the immersion tank 416 of FIG. 4 and the immersion tank lid 500. The seal 510 may preferably be constructed from, but not limited to, rubber, silicone, fluorosilicone, or fluorocarbon.

The first thermal sensor 525, second thermal sensor 520, and third thermal sensor 515 may be connected or in contact with the first heat source 535, second heat source 540, and third heat source 545. The first thermal sensor 525, second thermal sensor 520, and third thermal sensor 515 may measure and report the temperature of the first heat source 535, second heat source 540, and third heat source 545. It is preferable that the first thermal sensor 525, second thermal sensor 520, and third thermal sensor 515 be capable of operating while submersed in a fluid and accurately measure the temperature of first heat source 535, second heat source 540, and third heat source 545.

The cooled fluid from the heat exchanger 530 may be returned from the heat exchanger 275 through the heat exchanger removed heat return pipe 215 as shown in FIG. 2. The immersion tank lid 500 may preferably have a leak preventative connection to the heat exchanger removed heat return pipe 215.

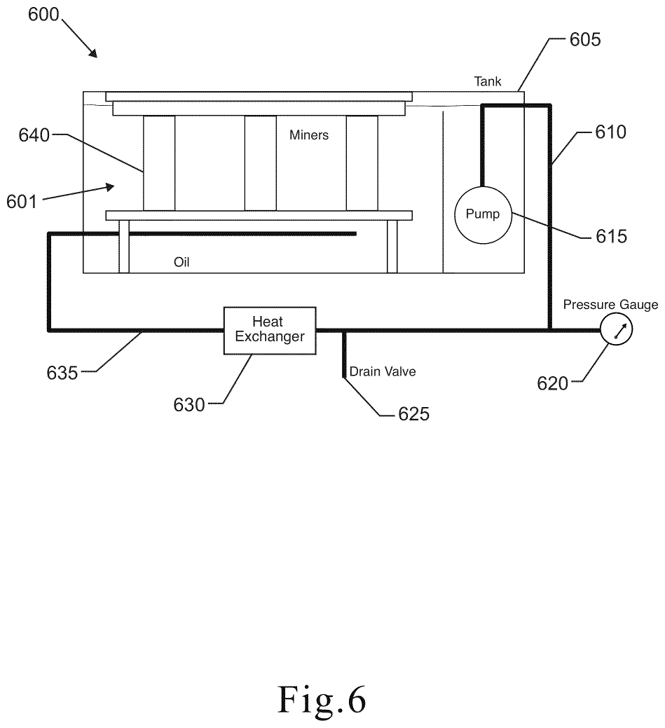

FIG. 6 is a block diagram of a heat harnessing heater heat generating side. The heat harnessing heater heat generating side 600 may comprise a fluid 601, immersion tank 605, heat exchanger removed heat inlet pipe 610, heat harnessing fluid pump 615, pressure gauge 620, drain valve 625, heat exchanger 630, heat exchanger removed heat return pipe 635, and heat source 640.

The heat harnessing fluid pump 615 may pump the fluid 601 from the immersion tank 605 to the heat exchanger 630 through the heat exchanger removed heat inlet pipe 610, where the heat exchanger 630 may transfer heat to a second fluid (not shown). The fluid 601 may then flow out of the heat exchanger 630 at a lower temperature and return to the immersion tank 605 through the heat exchanger removed heat return pipe 635. The flow of the fluid 601 may continuously flow or be pulsed by the heat harnessing fluid pump 615. The fluid 601, while in the immersion tank 605, may be in contact with heat sources such as the heat source 640 and absorb generated heat from the heat source 640.

As heat increases in the heat harnessing heater heat generating side 600, pressure may develop and potentially increase as the temperature rises in the heat harnessing heater heat generating side 600. The pressure gauge 620 may indicate the pressure and provide the pressure to a user interface, operation, or user. In the event that pressure rises outside of the levels that may be maintained by heat harnessing heater heat generating side 600, or in the event the fluid 601 may need to be removed, the drain valve 625 may allow pressure relief and removal of the fluid 601.

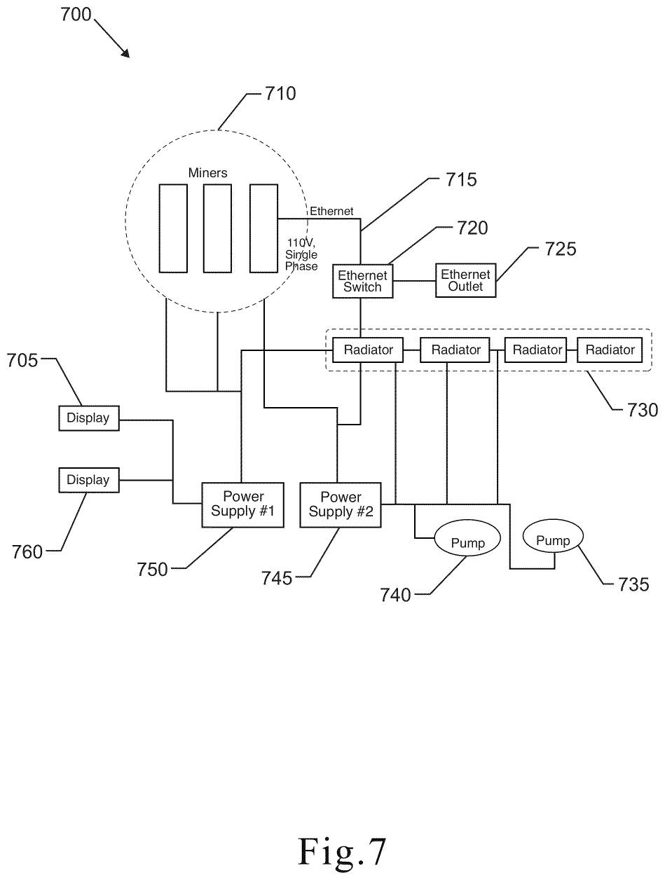

FIG. 7 is a block diagram of a heat harnessing heater electrical architecture. The heat harnessing heater electrical architecture 700 may comprise power supply 1 750 and power supply 2 745. Power supply 1 750 and power supply 2 745 may supply 240-volt dual phase electrical power, 110-volt single phase electrical power to a first display 705, heat sources 710, network switch 715, heater to network connection 725, radiator and fan 730, heat generating side fluid pump 735, space heating side fluid pump 740, and second display 760. Power supply 1 750 and power supply 2 745 may also provide lower direct current voltages.

The heater to network connection 725 may allow an external network connection to transfer broadband data. The network switch 720 may connect one or more heat sources 710 to a network, allowing the heat sources 710 to exchange data packets on a network. The network switch 715 may allow the heat sources 710 to connect to the network switch 720.

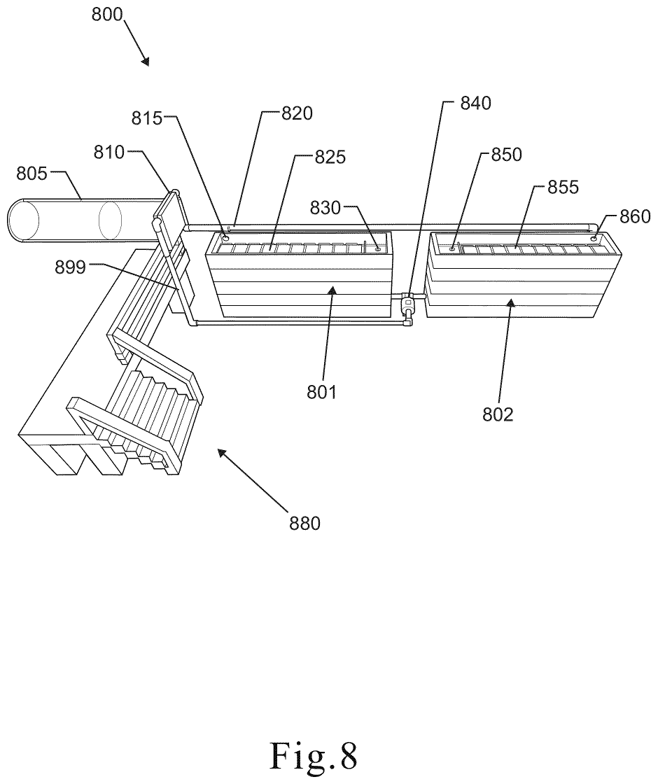

FIG. 8 is an alternate embodiment of a heat harnessing heater for a large space. The large space or building may require a larger array of heat sources 825 and 855, making a mobile embodiment less practical. A heat harnessing heater 800 may be a stationary heater. Heat harnessing heater 800 may comprise a first immersion tank 801, second immersion tank 802, ventilation duct 805, radiator and fan 810, immersion tank inlet 815, immersion tank cool supply pipe 820, heat sources 825, heated fluid supply 830, pump 840, heated fluid supply 850, heat sources 855, immersion tank cool supply 860, and platform 880.

The heat sources 825 and 855 may be computers, computer servers, or cryptominers. The heat sources 825 and 855 may generate excess heat that may transfer the generated heat to a fluid within the first immersion tank 801 and second immersion tank 802. Although the heat harnessing heater 800 is shown as only having two immersion tanks in FIG. 8, heat harnessing heater 800 may expand or contract to include many more or fewer immersion tanks. Cool fluid may enter the first immersion tank 801 through the immersion tank inlet 815 and into the second immersion tank 802 through the immersion inlet cool supply 860. Fluid may be heated inside the first immersion tank 801 and the second immersion tank 802 by the heat sources 825 and 855. Heated fluid may be pumped out of the first immersion tank 801 and second immersion tank 802 by the pump 840. Heated fluid may be pumped to the radiator and fan 810 through the radiator heated supply pipe 899. The radiator and fan 810 may remove heat from the heated fluid using ventilated air. The radiator and fan 810 may then ventilate air through the ventilation duct 805, which may provide heat to a large space or building. Fluid with heat removed is then returned to the first immersion tank 801 and the second immersion tank 802 through the immersion tank cool supply pipe 820.

As shown in FIG. 8, multiple immersion tanks may be connected to the pump 840. A larger array of immersion tanks may require more pumps 840.

As shown in FIG. 8, the platform 880 may be constructed to allow for maintenance to be performed or to monitor the heat harnessing heater 800.

Additionally, rows of heat sources 825 and 855 along with the first immersion tank 801 and the second immersion tank 802 may be stacked upon one another, creating an array as long as the heat source is submerged in liquid. In some embodiments, the arrays may be referred to as reservoirs.

In a preferred embodiment, the liquid may be a dielectric liquid or other liquid in which the cryptominers may be submerged and continue to function as expected.

Unless otherwise stated, all measurements, values, ratings, positions, magnitudes, sizes, locations, and other specifications that are set forth in this specification, including in the claims that follow, are approximate, not exact. They are intended to have a reasonable range that is consistent with the functions to which they relate and with what is customary in the art to which they pertain.

The foregoing description of the preferred embodiment has been presented for the purposes of illustration and description. While multiple embodiments are disclosed, still other embodiments will become apparent to those skilled in the art from the above detailed description. These embodiments are capable of modifications in various obvious aspects, all without departing from the spirit and scope of protection. Accordingly, the detailed description is to be regarded as illustrative in nature and not restrictive. Also, although not explicitly recited, one or more embodiments may be practiced in combination or conjunction with one another. Furthermore, the reference or non-reference to a particular embodiment shall not be interpreted to limit the scope of protection. It is intended that the scope of protection not be limited by this detailed description, but by the claims and the equivalents to the claims that are appended hereto.

Except as stated immediately above, nothing that has been stated or illustrated is intended or should be interpreted to cause a dedication of any component, step, feature, object, benefit, advantage, or equivalent, to the public, regardless of whether it is or is not recited in the claims.

What is claimed is:

1. A heat harnessing apparatus, comprising:
one or more waste heat sources;
one or more immersion tanks;
one or more pumps; and
one or more heat exchangers;
wherein said one or more immersion tanks, said one or more pumps, and said one or more heat exchangers contain an immersion fluid;
wherein said one or more pumps are configured to pump said immersion fluid from said one or more immersion tanks to and from said one or more heat exchangers through an immersion-exchanger pipe system;
wherein said one or more immersion tanks contain a one or more waste heat sources in fluidic communication with said immersion fluid;
wherein said one or more waste heat sources are configured to transfer a generated heat to said immersion fluid.

2. The heat harnessing apparatus of claim 1, wherein said immersion fluid is a dielectric fluid.

3. The heat harnessing apparatus of claim 2, wherein said immersion fluid is Bitcool dielectric fluid.

4. The heat harnessing apparatus of claim 1, wherein said one or more waste heat sources are cryptominers.

5. The heat harnessing apparatus of claim 1, wherein said one or more pumps are configured to be submersed in said immersion fluid;
wherein said one or more pumps, pump said immersion fluid and said generated heat into said one or more heat exchangers; whereby said one or more heat exchangers remove said generated heat from said immersion fluid;
wherein said pumps, pump said immersion fluid with said generated heat removed into said one or more immersion tanks.

6. The heat harnessing apparatus of claim 1, wherein said one or more heat exchangers are configured to transfer heat to one or more radiators.

7. The heat harnessing apparatus of claim 5, further including one or more fans;
wherein said one or more fans are configured to circulate a flow of air;
whereby said flow of air flows through said one or more radiators;
whereby said flow of air removes said generated heat from one or more radiators; and
said flow of air heats a space with said generated heat.

8. The heat harnessing apparatus of claim 1, wherein said system is a mobile heating apparatus;
wherein said mobile heating apparatus transfers said generated heat to one or a combination of one or more rooms, one or more spaces, or a building.

9. The heat harnessing apparatus of claim 1, further comprising;
a thermal sensor; and
one or more displays;
wherein said thermal sensors are configured to measure the temperature of said one or more waste heat sources; and
wherein said one or more displays are configured to display one or more system parameters and status.

10. A heat harnessing apparatus, comprising:
one or more cryptominers;
an immersion tank;
one or more pumps; and
one or more heat exchangers;
wherein said immersion tank, said one or more pumps, and said one or more heat exchangers contain an immersion fluid;
wherein said one or more pumps are configured to pump said immersion fluid from said immersion tank to and from said one or more heat exchangers through an immersion-exchanger pipe system;
wherein said immersion tank contains a one or more cryptominers in fluidic communication with said immersion fluid;
wherein said one or more cryptominers is configured to transfer a generated heat to said immersion fluid.

11. The heat harnessing apparatus of claim 10, wherein said one or more cryptominers are stacked into an array.

12. The heat harnessing apparatus of claim 10, further comprising a fan;
wherein said fan is configured to circulate surrounding air through said radiator;
whereby said circulated air heats one or a combination of one or more spaces, one or more rooms, or a building.

13. The heat harnessing apparatus from cryptominers of claim 11, further comprising one or more ventilation ducts;
wherein said one or more ventilation ducts are configured to allow a circulated air flow through said one or more ventilation ducts.

14. The heat harnessing apparatus from cryptominers of claim 13 wherein said circulated air flow transfers said harnessed heat throughout one or a combination of one or more rooms, one or more spaces, or building.

15. The heat harnessing apparatus from cryptominers of claim 10, wherein said one or more pumps are submersed in said immersion fluid in said one or more immersion tanks;
wherein said one or more pumps, pump said fluid and said generated heat into said one or more heat exchangers; wherein said one or more heat exchangers are configured to remove said generated heat from said fluid;
wherein said pumps, pump said fluid with said generated heat removed into said one or more immersion tanks.

16. A heat harnessing apparatus, comprising:
one or more computing devices;
one or more immersion tanks;
one or more pumps; and
one or more heat exchangers;
wherein said one or more immersion tanks is configured to contain an immersion fluid;
wherein said one or more pumps are configured to pump said immersion fluid from said one or more immersion tanks to and from said one or more heat exchangers though an immersion-exchanger pipe system;
wherein said one or more immersion tanks are comprise a cooled fluid inlet and a heated fluid outlet, wherein said fluid is configured to enter said one or more immersion tank through said cooled fluid inlet and said immersion fluid is configured to exit said one or more immersion tanks through said heated outlet;
wherein said one or more immersion tanks are configured to support said one or more computing devices;
wherein said immersion fluid is configured to be in fluidic communication with said one or more computing devices; and
wherein said one or more computing devices are configured to generate heat, and when in contact with said immersion fluid, are configured to transfer said generated heat to said immersion fluid.

17. The heat harnessing apparatus of claim 16, further comprising one or more fans and one or more dissipation systems;
wherein said one or more dissipation systems comprise one or more dissipator pumps, one or more radiators and one or more exchanger-dissipation pipe systems;
wherein said one or more exchanger-dissipation pipe systems contain a dissipation fluid;
wherein said one or more exchanger-dissipation pipe systems are configured to transfer heat from said one or more heat exchangers to said one or more radiators;
wherein said one or more fans are configured to blow an ambient air to transfer heat from said one or more radiators to an outside environment.

18. The heat harnessing apparatus of claim 16, wherein said outside environment is an agricultural setting.

19. The heat harnessing apparatus of claim 16, further comprising one or more air filters configured to prevent contaminants in said outside environment from interacting with said one or more dissipation systems.
